(19) United States
(12) Patent Application Publication
(10) Pub. No.: US 2004/0218647 A1
(43) Pub. Date: Nov. 4, 2004

(54) Semiconductor laser device and optical disc unit

(75) Inventors: Shuichi Hirukawa, Nara-shi (JP); Hidenori Kawanishi, Oxford (GB); Kei Yamamoto, Nara-shi (JP); Hiroyuki Nishimoto, Ikeda-shi (JP)

Correspondence Address: MORRISON & FOERSTER LLP, 1650 TYSONS BOULEVARD, SUITE 300, MCLEAN, VA, 22102, US

(73) Assignee: SHARP KABUSHIKI KAISHA, Osaka-Shi (JP)

(21) Appl. No.: 10/806,466

(22) Filed: Mar. 23, 2004

(30) Foreign Application Priority Data
Mar. 26, 2003 (JP) P2003-085098

(51) Int. Cl. H01S 5/00

(52) U.S. Cl. 372/46; 372/45

(57) ABSTRACT

To provide a semiconductor laser device which is highly reliable even in high-power operation and has a long lifetime, and an optical disc unit using the semiconductor laser device. A semiconductor laser device having an oscillation wavelength of larger than 760 nm and smaller than 800 nm in which, on an n-type GaAs substrate (101), there are stacked in sequence an n-type first and second lower cladding layers (103, 104), a lower guide layer (105), a quantum well active layer (107), an upper guide layer (109) and a p-type upper cladding layer (110). The quantum well active layer (107) is composed of two InGaAsP compressively strained quantum well layers and three InGaAsP barrier layers alternately disposed in a manner such that an n-side barrier layer is present on a side of the lower guide layer (105) and that a p-side barrier layer is present on a side of the upper guide layer (109). The n-side barrier layer is set to have a thickness of 130 Å, which causes holes hard to tunnel. The p-side barrier layer is set to have a thickness of 50 Å, which facilitates tunneling of holes.

This Nonprovisional application claims priority under 35 U.S.C. §119(a) on Patent Application No. P2003-085098 filed in Japan on Mar. 26, 2003, the entire contents of which are hereby incorporated by reference.

### BACKGROUND OF THE INVENTION

The present invention relates to a semiconductor laser device and an optical disc unit, in particular to a semiconductor laser device that can realize high output and high reliability, and an optical disc unit using the same.

Semiconductor laser devices are used for optical communication devices, optical recording devices and so on. Recently, there are increasing needs for high speed and large capacity in such devices. In order to meet the demands, research and development has been advanced for improving various characteristics of semiconductor laser devices.

Among them, a 780 nm band semiconductor laser device, which is used for an optical disc unit such as a conventional CD or CD-R/RW, is usually made of an AlGaAs materials. Since demands for high-speed writing have been increasing also in the CD-R/RW, high-output semiconductor laser devices are requested in order to satisfy these demands.

As a conventional AlGaAs semiconductor laser device, there is one as shown in FIG. 11 (see, e.g., JP 11-274644 A). The structure of the AlGaAs semiconductor laser device will be briefly described. As shown in FIG. 11, on an n-type GaAs substrate 501, there are an n-type GaAs buffer layer 502, an n-type Al_{0.5}Ga_{0.5}As lower cladding layer 503, an Al_{0.35}Ga_{0.65}As lower guide layer 504, a multiquantum well active layer 505 composed of two Al_{0.12}Ga_{0.88}As well layers (each layer having a thickness of 80 Å) and three Al_{0.35}Ga_{0.65}As barrier layers (each layer having a thickness of 50 Å) disposed alternately, an Al_{0.35}Ga_{0.65}As upper guide layer 506, a p-type Al_{0.5}Ga_{0.5}As first upper cladding layer 507 and a p-type GaAs etching stopper layer 508 that are stacked in this order. A mesa stripe-shaped p-type Al_{0.5}Ga_{0.5}As second upper cladding layer 509 and a eaves-shaped p-type GaAs cap layer 510 are sequentially formed on a surface of the etching stopper layer 508. An n-type Al_{0.7}Ga_{0.3}As first current blocking layer 511 and an n-type GaAs second current blocking layer 512 are stacked on both sides of the second upper cladding layer 509, so that regions other than the mesa stripe portion are defined as current constriction portions. A p-type GaAs planarizing layer 513 is formed on the second current blocking layer 512, and a p-type GaAs contact layer 514 is laid on the entire surface.

The semiconductor laser device has a threshold current of 35 mA and a COD (Catastrophic Optical Damage) level of about 160 mW.

However, in the semiconductor laser device that employs the AlGaAs material, “end-face damage” caused by COD is liable to occur on laser light-emitting end faces during the high-power operation, due to influence of active Al (aluminum) atoms. As a result, such a semiconductor laser device only had a maximum optical output of about 160 mW. The end-face damage caused by COD is presumed to occur by the following mechanism. In the end faces of a resonator, because Al is easily oxidized, a surface level is formed thereby. Carriers injected into the active layer are relaxed through the level, when heat is emitted. Therefore, the temperature increases locally. The increase in the temperature reduces the bandgap of the active layer in the vicinity of the end faces. As a result, absorption of laser light in the vicinity of the end faces increases, and the number of carriers that are relaxed through the surface level increases resulting in further generation of heat. By repeating such a positive feedback, the end faces are finally melted resulting in stop of oscillation. Since Al is contained in an active region in the conventional semiconductor laser device, the end-face damage on the basis of the above principle becomes a big problem.

The present inventors have proceeded with the study on high-output semiconductor laser devices that employ InGaAsP materials that contain no Al (Al-free materials) in the active region. As a result, a semiconductor laser device having a maximum optical output of up to almost 250 mW was realized, but sufficient reliability and temperature characteristics were not obtained. Inspecting this semiconductor laser device, the inventors found the possibility that carriers injected in the active region were liable to leak to the outside of the active region in comparison with a conventional laser device under high-temperature atmosphere or in high-power operation.

### SUMMARY OF THE INVENTION

It is an object of the present invention to provide a semiconductor laser device that is highly reliable even in high-power operation and has a long lifetime, and an optical disc unit using the semiconductor laser device.

In order to achieve the above object, there is provided a semiconductor laser device in which, on an n-type GaAs substrate, there are at least an n-type lower cladding layer, a lower guide layer, an InGaAsP quantum well active layer composed of one or a plurality of well layers and a plurality of barrier layers alternately disposed, an upper guide layer and a p-type upper cladding layer that are stacked, wherein

the quantum well active layer is stacked so that an n-side barrier layer is present on a side of the lower guide layer and a p-side barrier layer is present on a side of the upper guide layer,

said semiconductor laser device has an oscillation wavelength of more than 760 nm and less than 800 nm, and the n-side barrier layer has a thickness of 70 Å or more. According to the present invention, the above semiconductor laser device having a higher COD level than that of an AlGaAs semiconductor laser device can be fabricated. Furthermore, compared with the AlGaAs semiconductor laser device, leakage of carriers (holes in particular) from the active region can be reduced. Therefore, it is possible to obtain a high-output semiconductor laser device using a GaAs substrate (in particular, a 780 nm band high-output semiconductor laser device for use of CD-R/RW) that has favorable temperature characteristics in a high-output operation. The thickness of the n-side barrier layer is preferably within such thickness that it exerts quantum effects.

In one embodiment of the present invention, the p-side barrier layer has a smaller thickness than that of the n-side barrier layer. According to the embodiment, tunneling of holes through the p-side barrier layer is facilitated, so that the holes are easily injected into the active region. This makes it possible to obtain a semiconductor laser device having good temperature characteristics, reliability and a long lifetime in high-output operation. When the p-side barrier layer has a thickness of less than 70 Å, the similar effect is suitably achievable.

Also, there is provided a semiconductor laser device in which, on a p-type GaAs substrate, there are at least a p-type lower cladding layer, a lower guide layer, an InGaAsP quantum well active layer composed of one or a plurality of well layers and a plurality of barrier layers alternately disposed, an upper guide layer and an n-type upper cladding layer that are stacked, wherein

the quantum well active layer is stacked so that a p-side barrier layer is present on a side of the lower guide layer and an n-side barrier layer is present on a side of the upper guide layer,

said semiconductor laser device has an oscillation wavelength of more than 760 nm and less than 800 nm, and the n-side barrier layer has a thickness of 70 Å or more. According to the present invention, a semiconductor laser device having a higher COD level than that of the AlGaAs semiconductor laser device can be fabricated. Furthermore, leakage of carriers (holes in particular) from the active region is reduced. Therefore, it is possible to obtain a high-output semiconductor laser device that has favorable temperature characteristics in a high-power operation. The thickness of the n-side barrier layer is preferably within such thickness that it exerts quantum effects.

In one embodiment of the present invention, the p-side barrier layer has a smaller thickness than that of the n-side barrier layer. According to the embodiment, tunneling of holes through the p-side barrier layer is facilitated, so that the holes are easily injected into the active region. Thus, it is possible to obtain a semiconductor laser device that has favorable temperature characteristics, reliability and a lifetime in a high-power operation. When the p-side barrier layer has a thickness of less than 70 Å, the similar effect is suitably achieved.

In one embodiment of the present invention, the upper guide layer and the lower guide layer are formed of AlGaAs. According to the embodiment. Therefore, AlGaAs is disposed in a manner so as not to be immediately adjacent to the well layer(s) where radiative recombination occurs. This makes it possible to ensure the reliability and, at the same time, sufficiently suppress an overflow of carriers (electrons in particular) by a conduction band bottom energy level (Ec) of AlGaAs. This realizes a semiconductor laser device having high reliability and a long lifetime.

In one embodiment of the present invention, an Al mole fraction of the upper guide layer and the lower guide layer is more than 0.2. According to the embodiment, the above effect is more favorably achievable.

In one embodiment of the present invention, the well layer(s) has a compressive strain. According to the embodiment, the well layer made of InGaAsP having the compressive strain is formed on the GaAs substrate. Therefore, the oscillation threshold current is reduced and this realizes a high-output semiconductor laser device which is highly reliable particularly in a 780 nm band and which has a long lifetime.

In one embodiment of the present invention, a quantity of an absolute value of the compressive strain is not more than 3.5%. According to the embodiment, the above effect is favorably obtained.

In one embodiment of the present invention, the barrier layers have a tensile strain. According to the embodiment, the strain quantity of the barrier layers compensates the compressive strain of the well layer(s) and thus a strained quantum well active layer having more stable crystals is fabricated. Therefore, a semiconductor laser device with high reliability is realized.

In one embodiment of the present invention, a quantity of an absolute value of the tensile strain is not more than 3.5%. According to the embodiment, the above effect is favorably obtained.

Also, there is provided an optical disc unit wherein the above semiconductor laser device is used. According to the present invention, this optical disc unit operates with higher optical power than conventional. Therefore, data read-and-write operations are implementable even if the rotational speed of the optical disk is made higher than conventional. Accordingly, the access time to optical disks, which has hitherto mattered particularly in write operations, becomes much shorter than in a system using the conventional semiconductor laser device. This makes it feasible to provide an optical disk unit which is operable more comfortably.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a cross section of a semiconductor laser device according to a first embodiment of the present invention, taken along a plane perpendicular to a stripe direction of the device;

FIG. 2 is a cross section of the semiconductor laser device after completion of a first crystal growth and masking process, taken along the plane perpendicular to the stripe direction;

FIG. 3 is a cross section of the semiconductor laser device after completion of an etching process for forming a mesa stripe, taken along the plane perpendicular to the stripe direction;

FIG. 4 is a cross section of the semiconductor laser device after completion of a process of crystal growth for buried current blocking layers, taken along the plane perpendicular to the stripe direction;

FIG. 5 is a simplified diagram of an energy band profile of the semiconductor laser device;

FIG. 6 is a graph showing reliability of the semiconductor laser devices that depends on structures of their barrier layers;

FIG. 7 is a graph showing reliability of the semiconductor laser devices that depends on compressive-strain quantities of their well layers;

FIG. 8 is a graph showing a relationship between an Al mole fraction in a guide layer of the semiconductor laser device and a temperature characteristic (To);

FIG. 9 is a schematic view showing a relationship of a temperature characteristic and injection efficiency in regard to respective thicknesses of an n-side and a p-side barrier layer;

FIG. 10 is a schematic view of an optical disc unit according to a second embodiment of the present invention; and

FIG. 11 is a cross section of a conventional semiconductor laser device, taken along a plane perpendicular to a stripe direction of the device.

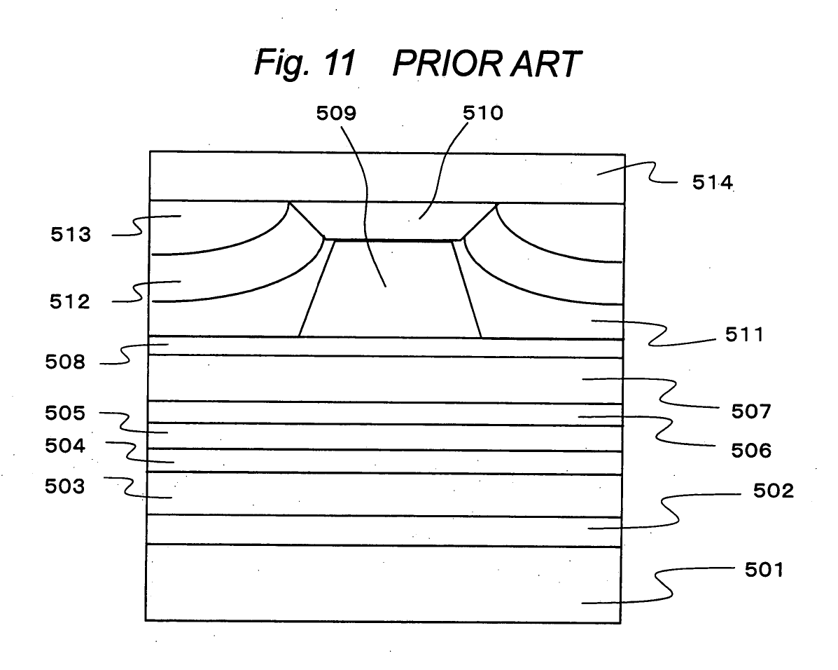

### DETAILED DESCRIPTION OF THE PREFERRED EMBODIMENTS

A semiconductor laser device, a method of producing the same and an optical disc unit of the present invention will hereinafter be described by embodiments illustrated.

(First Embodiment)

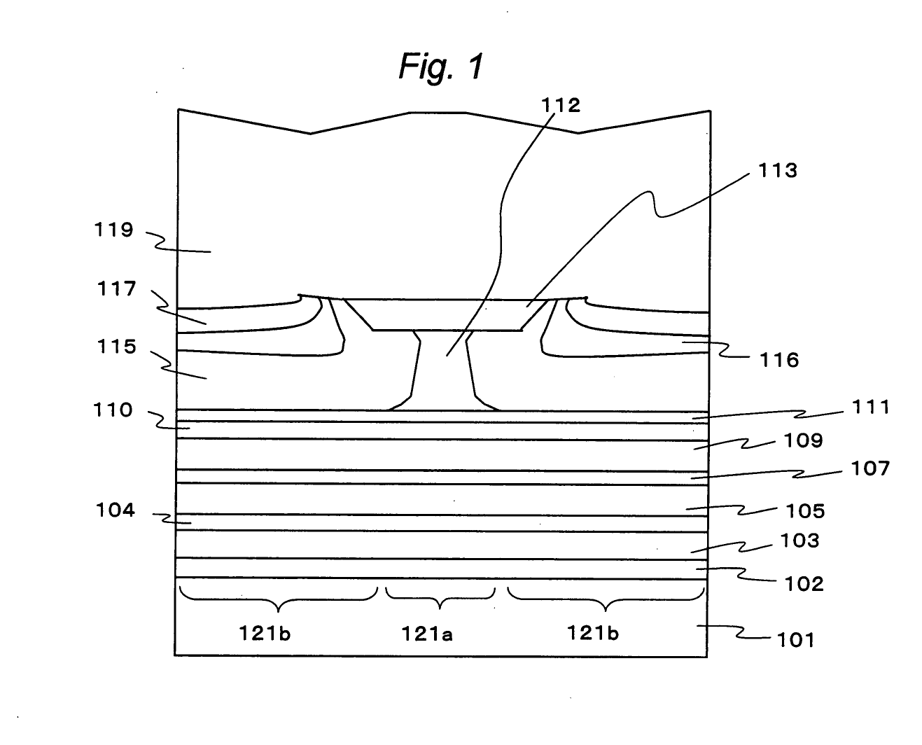

FIG. 1 is a view showing a semiconductor laser device of the first embodiment. In this semiconductor laser device, as shown in FIG. 1, on an n-type GaAs substrate 101, there are stacked in sequence an n-type GaAs buffer layer 102, an n-type Al_{0.453}Ga_{0.547}As first lower cladding layer 103, an n-type Al_{0.5}Ga_{0.5}As second lower cladding layer 104, an Al_{0.4278}Ga_{0.5722}As lower guide layer 105, a strained multiquantum well active layer 107, an Al_{0.4278}Ga_{0.5722}As upper guide layer 109, a p-type Al_{0.4885}Ga_{0.5115}As first upper cladding layer 110, and a p-type GaAs etching stopper layer 111. Also, on the etching stopper layer 111, there are provided a mesa stripe-shaped p-type Al_{0.4885}Ga_{0.5115}As second upper cladding layer 112 and a GaAs cap layer 113, and both sides of the mesa stripe-shaped p-type Al_{0.4885}Ga_{0.5115}As second upper cladding layer 112 and the GaAs cap layer 113 are filled with an n-type Al_{0.7}Ga_{0.3}As first current blocking layer 115, an n-type GaAs second current blocking layer 116, and a p-type GaAs planarizing layer 117, which layers define a light/current constriction area. Further, a p-type GaAs cap layer 119 is provided on the entire surface. The semiconductor laser device has a mesa stripe portion 121a and lateral portions 121b provided on both lateral sides of the mesa stripe portion 121a.

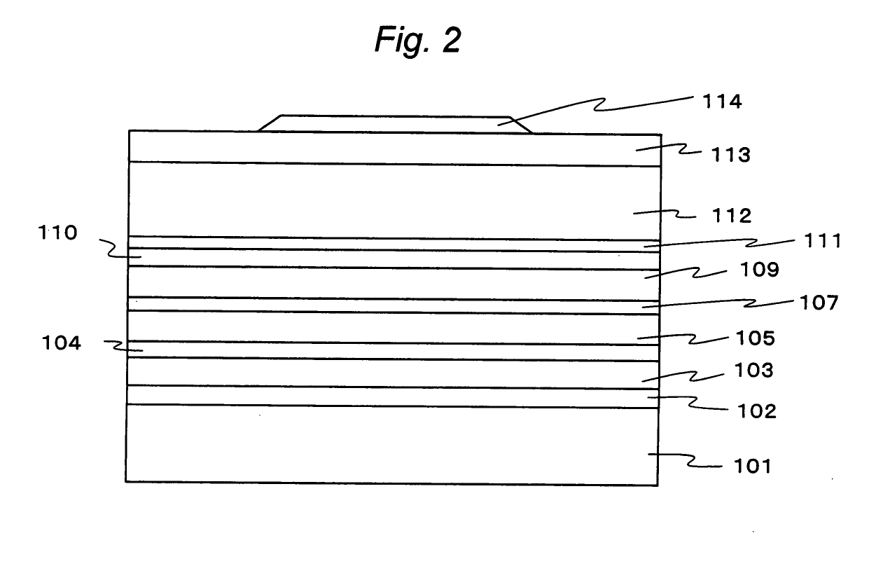

Next, with reference to FIGS. 2-4, a process for fabricating the semiconductor laser structure will be described. As shown in FIG. 2, on an n-type GaAs substrate 101 having a (100) plane, there are stacked in sequence an n-type GaAs buffer layer 102 (thickness of 0.5 μm), an n-type Al_{0.453}Ga_{0.547}As first lower cladding layer 103 (thickness of 3.0 μm), an n-type Al_{0.5}Ga_{0.5}As second lower cladding layer 104 (thickness of 0.24 μm), an Al_{0.4278}Ga_{0.5722}As lower guide layer 105 (thickness of 1850 Å), a multiquantum well active layer 107 composed of two In_{0.1863}Ga_{0.8137}As_{0.6965}P_{0.3035} compressively-strained quantum well layers (strain of 0.39%, each layer having a thickness of 60 Å) and three In_{0.0717}Ga_{0.9283}As_{0.6238}P_{0.3762} barrier layers (strain of −1.32%, the layers having a thickness of 130 Å, 50 Å, 50 Å, respectively, from a substrate side, a layer closest to the substrate serving as an n-side barrier layer, a layer farthest from the substrate serving as a p-side barrier layer) disposed alternately, an Al_{0.4278}Ga_{0.5722}As upper guide layer 109 (thickness of 950 Å), a p-type Al_{0.4885}Ga_{0.5115}As first upper cladding layer 110 (thickness of 0.165 μm), a p-type GaAs etching stopper layer 111 (thickness of 30 Å), a p-type Al_{0.4885}Ga_{0.5115}As second upper cladding layer 112 (thickness of 1.28 μm) and a GaAs cap layer 113 (thickness of 0.75 μm) through crystal growth by metal organic chemical vapor deposition.

Further, referring to FIG. 2, a resist mask 114 (mask width of 5.5 μm) is formed on a portion where a mesa-stripe portion is to be formed, by a photolithography process so that the mesa stripe portion will extend in the (011) direction.

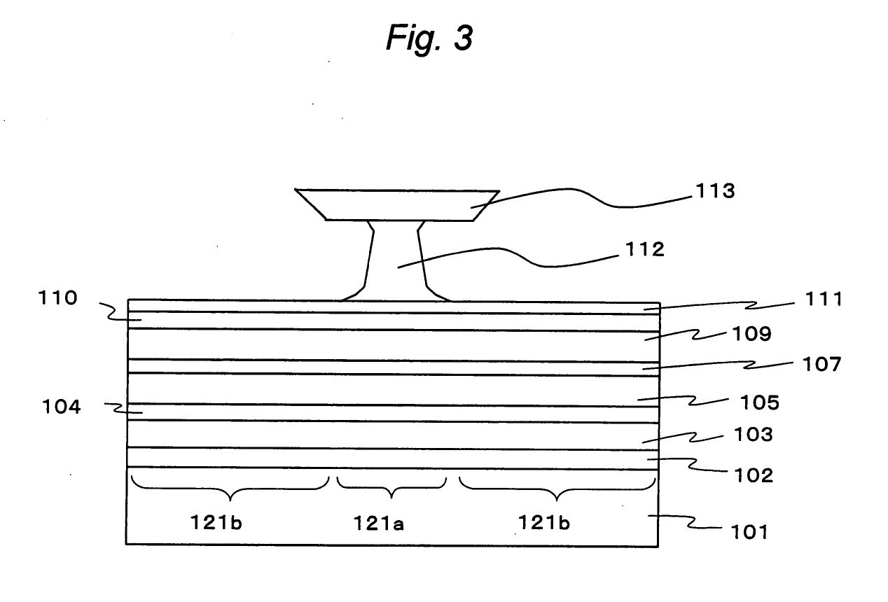

Next, as shown in FIG. 3, etching is applied to portions other than the resist mask 114 (shown in FIG. 2) to thereby form a mesa-stripe portion 121a. This etching is carried out in two steps using a mixed aqueous solution of sulfuric acid and hydrogen peroxide, and hydrofluoric acid, until immediately above the etching stopper layer 111. The fact that the etching rate of GaAs by hydrofluoric acid is low enables planarization of the etched surface and control of the width of the mesa stripe portion. The etching depth is 1.95 μm, and the mesa-stripe has a width of about 2.5 μm in its lowermost portion. After the etching, the resist mask 114 is removed.

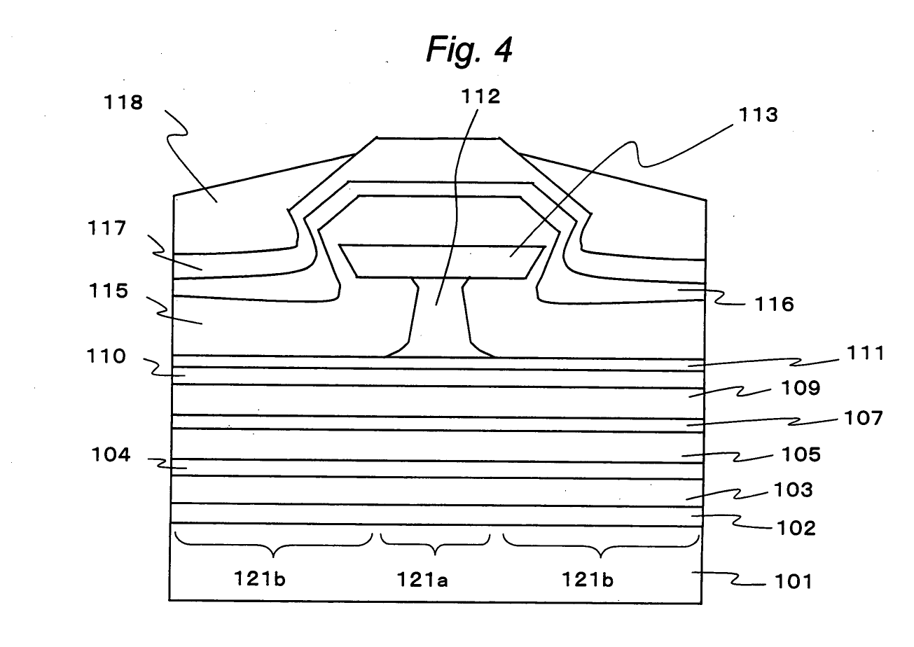

Subsequently, as shown in FIG. 4, an n-type Al_{0.7}Ga_{0.3}As first current blocking layer 115 (thickness of 1.0 μm), an n-type GaAs second current blocking layer 116 (thickness of 0.3 μm) and a p-type GaAs planarizing layer 117 (thickness of 0.65 μm) are sequentially crystal-grown by metal organic chemical vapor deposition to form a light/current constriction region.

After that, as shown in FIG. 4, a resist mask 118 is formed only on both the lateral portions 121b by the photolithography process. Subsequently, the current blocking layers above the mesa stripe portion 121a are removed by etching. The etching is carried out in two steps using a mixed aqueous solution of ammonia and hydrogen peroxide and a mixed aqueous solution of sulfuric acid and hydrogen peroxide.

Thereafter, the resist mask 118 is removed, and a p-type GaAs cap layer 119 (thickness of 2.0 μm), shown in FIG. 1, is formed. In this manner, a semiconductor laser device having the structure shown in FIG. 1 is fabricated.

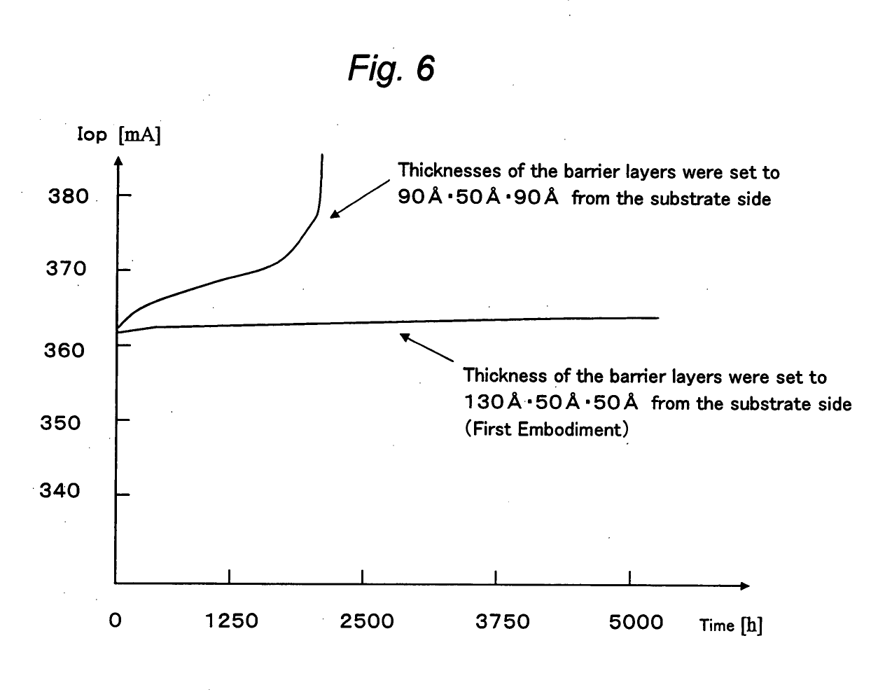

In the first embodiment, the thicknesses of the three barrier layers of the multiquantum well active layer 107 were set to 130 Å, 50 Å and 50 Å, respectively, from the substrate side, whereby stable operation for 5000 hours or more was confirmed in reliability tests under the conditions of: an oscillation wavelength of 780 nm, a temperature of 70° C., and a pulse of 260 mW as seen from FIG. 6. So far, the present inventors have studied a semiconductor laser devices that employ an InGaAsP quantum well active layer on the GaAs substrate. This time, a semiconductor laser device having a higher COD level compared with the one that employs AlGaAs was fabricated. In FIG. 6, Iop denotes a current value when the output of the semiconductor laser device is 260 mW. Further, as a comparative example, the thicknesses of the three barrier layers of the multiquantum well active layer 107 were set to 90 Å, 50 Å and 90 Å, respectively, from the substrate side, and reliability tests were conducted under the same conditions. As a result, as shown in an upper side of FIG. 6, the end face damage occurred for a short period of time.

In order to further improve temperature characteristics of the semiconductor laser device in high-output operation, the thickness of the n-side barrier layer was set to 130 Å whereby the characteristic temperature To was raised to 210 K. It is considered that provision of the n-side barrier layer having a thickness of 130 Å as in the present embodiment reduced leakage of carriers (holes in particular) from the active region, which led to an improvement in the characteristics.

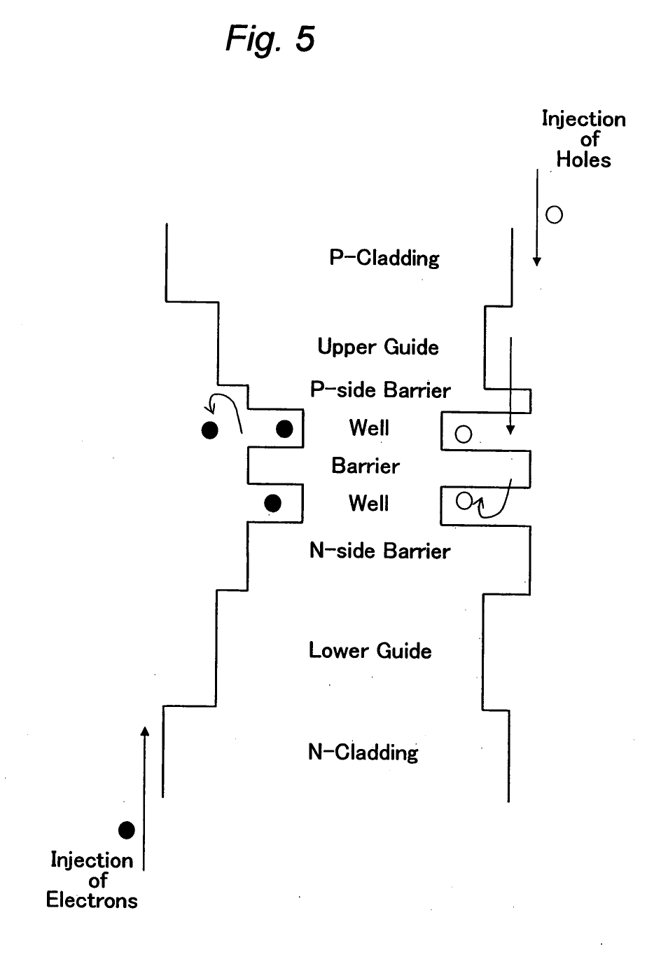

FIG. 5 schematically shows an energy band profile of the semiconductor laser device of the present embodiment. In the 780 nm band InGaAsP quantum well active layer on the GaAs substrate, a valence band top energy level (Ev) of barrier layers is lower than the energy level (Ev) of the lower guide layer. That is, there is formed a structure in which holes are apt to leak from the active region by tunneling at an interface between the lower guide layer and the barrier layer. This is considered to deteriorate the characteristics. For that reason, the thickness of the n-side barrier layer is set to as thick as 130 Å in order to cause holes hard to tunnel, whereby the effect of reducing leakage of holes is achieved. It is sufficient if the thickness of the n-side barrier layer is 70 Å or more, and if the thickness thereof is 100 Å or more, the above effect is achieved more optimally. The n-side barrier layer herein indicates a barrier layer closest to the substrate (a left side in FIG. 5) among a plurality of barrier layers.

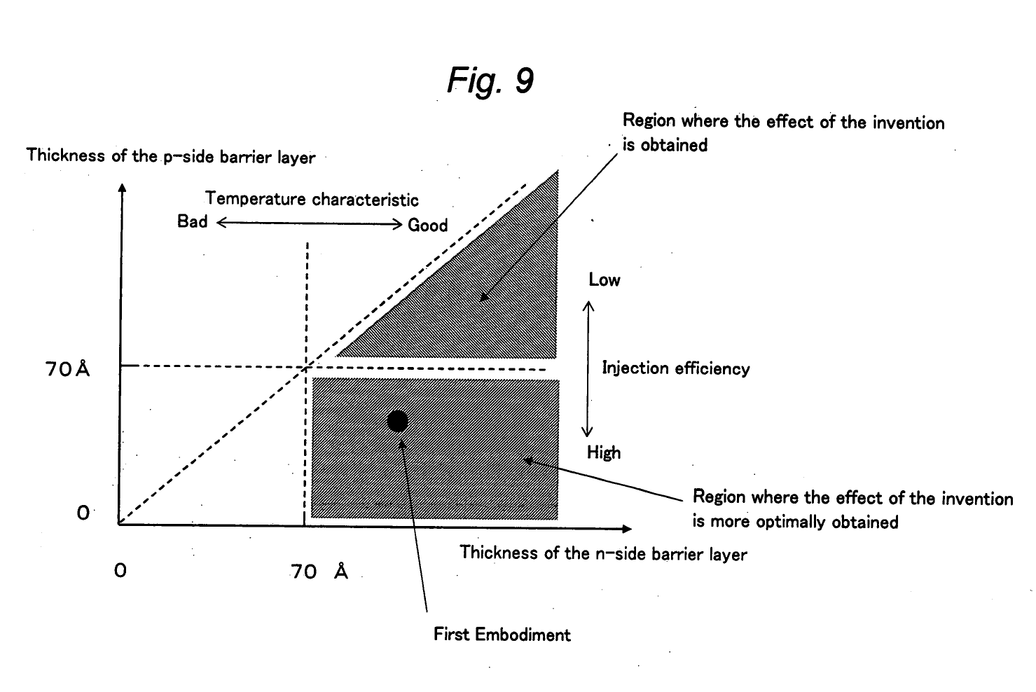

In the present embodiment, setting the thickness of the p-side barrier layer to 50 Å makes it possible to fabricate a semiconductor laser device having favorable reliability in high-power operation. Similarly, in the 780 nm-band InGaAsP quantum well active layer on the GaAs substrate as in the present embodiment, since the valence band top energy level (Ev) of the barrier layers is lower than the energy level (Ev) of the upper guide layer, there is formed a high barrier structure for holes. As a result, injection efficiency into the active region is lowered, presumably causing deterioration of the characteristic temperature, reliability and lifetime. For that reason, the thickness of the p-side barrier layer is set to as thin as 50 Å in order for holes to tunnel easily, whereby a semiconductor laser device having good reliability in high-power operation can be fabricated as shown in FIG. 6. It is sufficient if the thickness of the p-side barrier layer is not more than 70 Å, and if the thickness thereof is not more than 50 Å, the above effect is achieved more optimally. The p-side barrier layer herein indicates a barrier layer farthest from the substrate (a right side in FIG. 5) among the plurality of barrier layers. The relationship of a temperature characteristic and injection efficiency in regard to respective thicknesses of the n-side and the p-side barrier layer is shown in FIG. 9. As shown in FIG. 9, in a region where the n-side barrier layer has a thickness of 70 Å or more and the p-side barrier layer has a smaller thickness than that of the n-side barrier layer, the above effect is achieved. Especially, within the above region, in a region where the p-side barrier layer has a thickness of not more than 70 Å, the above effect is more optimally obtained.

In the present embodiment, the upper guide layer is formed of AlGaAs. Thus, AlGaAs is disposed in a manner so as not to be immediately adjacent to the well layer where radiative recombination occurs. This makes it possible to ensure the reliability and, at the same time, sufficiently suppress an overflow of carriers (electrons in particular) by a conduction band bottom energy level (Ec) of AlGaAs. When producing an Al-free semiconductor laser device in order to obtain high reliability, all the layers including guide layers and cladding layers are usually made Al-free using InGaP and so on. However, in the first embodiment, AlGaAs with an Al mole fraction of more than 0.2, by which a well-balanced conduction band energy difference (ΔEc) from the well layer(s) formed of InGaAsP having an oscillation wavelength of 780 nm is obtained, is provided as the guide layer.

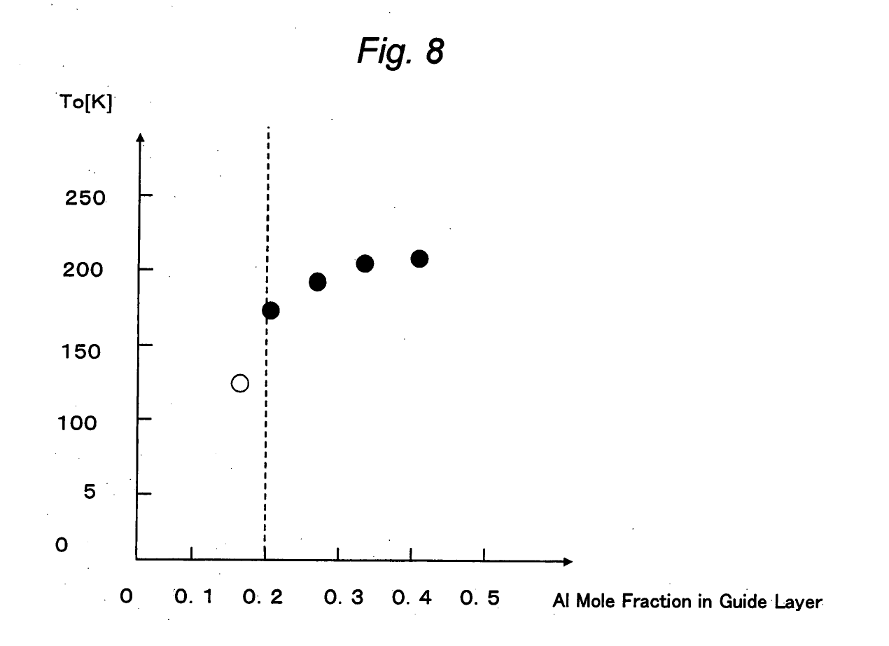

FIG. 8 is a graph showing the relationship between an Al mole fraction and a characteristic temperature (To). As shown in FIG. 8, it was confirmed that the temperature characteristics were improved in the case of the guide layer of AlGaAs in which the Al mole fraction was more than 0.2, so that sufficiently high reliability was achieved.

Since the compressively strained well layer(s) formed of InGaAsP on the GaAs substrate is used in the present embodiment, the oscillation threshold current is reduced, whereby a semiconductor laser device which has high reliability in high-power operation particularly in the 780 nm band and which has a long lifetime is realized. Furthermore, since the compressive-strain quantity of the compressively strained well layer(s) is not more than 3.5%, the above effect is optimally obtained. The strain quantity is herein represented by:

(a₁−a_{GaAs})/a_{GaAs}

where a_{GaAs} is a lattice constant of the GaAs substrate, and a₁ is a lattice constant of the well layer(s). If the value of the strain quantity is positive, the strain is called a compressive strain, and if the value is negative, it is called a tensile strain.

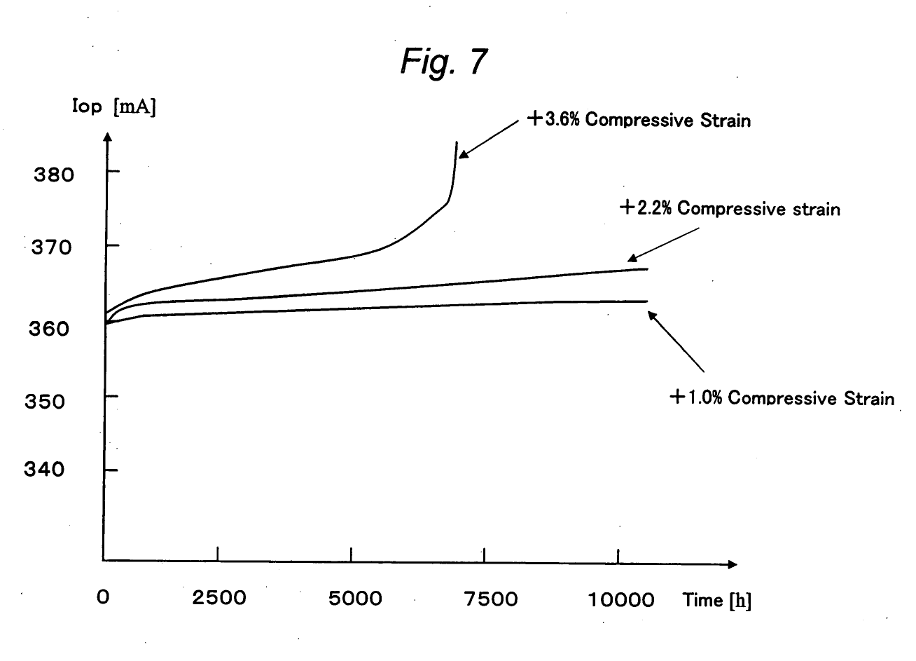

FIG. 7 is a graph showing the reliability (70° C., 260 mW) of the semiconductor laser devices that depends on compressive-strain quantities of their well layers. It can be seen that if the compressive-strain quantity exceeds 3.5%, the reliability deteriorates. It is considered that this is attributable to deterioration of crystallinity due to an excessively large compressive-strain quantity of the well layers.

Since the barrier layers each formed of InGaAsP and having a tensile strain are used in the first embodiment, they compensate the strain quantity of the well layers having a compressive strain, so that a strained quantum well active layer with more stable crystals can be fabricated. Consequently, a semiconductor laser device with high reliability can be realized. Furthermore, the tensile-strain quantity of not more than 3.5% makes it possible to obtain the above effect favorably.

Although the first embodiment has a buried ridge structure, the present invention is not limited thereto. The same effect may be achieved in any structure including ridge structure, internal stripe structure, and buried heterostructure.

Although an n-type substrate is used in the present embodiment, the same effect may be achieved by using a p-type substrate and replacing the n type and the p type of the layers with each other in the above embodiment. Namely, if the thickness of the barrier layer on the side, where holes are injected into the quantum well active layer, is set smaller, and the thickness of the barrier layer on the side, where electrons are injected into the quantum well active layer, is set larger, the same effect may be achieved.

Although the wavelength of 780 nm is used, it is not limited thereto. The same effect may be achieved if the wavelength is more than 760 nm and less than 800 nm, namely, in the so-called 780 nm band. At an interface between semiconductor layers formed of different materials, namely at an interface of the upper guide layer and the barrier layer, and at an interface of the lower guide layer and the barrier layer, an interface protective layer formed of GaAs, for example, may be provided. Furthermore, although the thickness of the p-type GaAs cap layer 119 is set to approximately 2.0 μm, it may be formed to a larger thickness of approximately 50 μm.

(Second Embodiment)

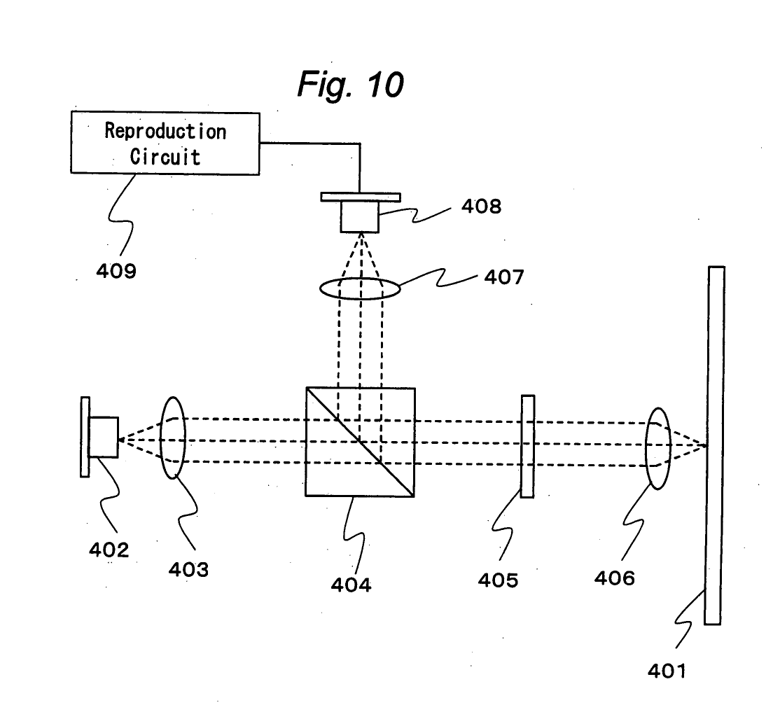

FIG. 10 is a view showing one example of the structure of an optical disc unit that employs a semiconductor laser device according to the present invention. This optical disk unit operates to write data on an optical disk 401 or reproduce data written on the optical disk. In this optical disc unit, a semiconductor laser device 402 of the first embodiment is included as a light-emitting device for use in those operations.

This optical disk unit will be described in more detail. In this optical disk unit, for write operations, signal light emitted from the semiconductor laser device 402 passes through a collimator lens 403, becoming parallel light, and is transmitted by a beam splitter 404. Then, after its polarized state is adjusted by a λ/4 polarizer 405, the signal light is converged by an irradiation objective lens 406 to thereby irradiate the optical disk 401. For read operations, a laser beam with no data signal superimposed on the laser beam travels along the same path as in the write operation, irradiating the optical disk 401. Then, the laser beam reflected by the surface of the optical disk 401, on which data has been recorded, passes through the laser-beam irradiation objective lens 406 and the λ/4 polarizer 405, and is thereafter reflected by the beam splitter 404 so as for its traveling direction to be changed by 90°. Subsequently, the laser beam is focused by a reproductive light objective lens 407 and applied to a signal-detection photodetector device 408. Then, in the signal-detection photodetector device 408, a data signal read from the optical disk 401 is transformed into an electric signal according to the intensity of the incident laser beam, and reproduced to the original information signal by a signal-light reproduction circuit 409.

The optical disk unit of the present embodiment employs the semiconductor laser device, as described above, which operates with higher optical power than conventional. Therefore, data read-and-write operations are implementable even if the rotational speed of the optical disk is increased to be higher than conventional. Accordingly, the access time to optical disks, which has hitherto mattered particularly in write operations, can be reduced to a large extent. This makes it feasible to provide an optical disk unit which allows more comfortable manipulation.

This embodiment has been described on a case where the semiconductor laser device of the present invention is applied to a recording and playback type optical disk unit. However, needless to say, the semiconductor laser device of this invention is applicable also to optical-disc recording units or optical-disc playback units using the 780 nm wavelength band.

The semiconductor laser device and the optical disc unit of the present invention should not be construed as being limited to the embodiments illustrated above. It is a matter of course that various modifications such as the number of well layers/barrier layers and thicknesses of such layers can be made without departing from the spirit of the invention.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor laser device in which, on an n-type GaAs substrate, there are at least an n-type lower cladding layer, a lower guide layer, an InGaAsP quantum well active layer composed of one or a plurality of well layers and a plurality of barrier layers alternately disposed, an upper guide layer and a p-type upper cladding layer that are stacked, wherein
the quantum well active layer is stacked so that an n-side barrier layer is present on a side of the lower guide layer and a p-side barrier layer is present on a side of the upper guide layer,
said semiconductor laser device has an oscillation wavelength of more than 760 nm and less than 800 nm, and the n-side barrier layer has a thickness of 70 Å or more.

2. The semiconductor laser device according to claim 1, wherein
the p-side barrier layer has a smaller thickness than that of the n-side barrier layer.

3. The semiconductor laser device according to claim 1, wherein
the p-side barrier layer has a thickness of less than 70 Å.

4. A semiconductor laser device in which, on a p-type GaAs substrate, there are at least a p-type lower cladding layer, a lower guide layer, an InGaAsP quantum well active layer composed of one or a plurality of well layers and a plurality of barrier layers alternately disposed, an upper guide layer and an n-type upper cladding layer that are stacked, wherein
the quantum well active layer is stacked so that a p-side barrier layer is present on a side of the lower guide layer and an n-side barrier layer is present on a side of the upper guide layer,
said semiconductor laser device has an oscillation wavelength of more than 760 nm and less than 800 nm, and the n-side barrier layer has a thickness of 70 Å or more.

5. The semiconductor laser device according to claim 4, wherein
the p-side barrier layer has a smaller thickness than that of the n-side barrier layer.

6. The semiconductor laser device according to claim 4, wherein
the p-side barrier layer has a thickness of less than 70 Å.

7. The semiconductor laser device according to claim 1, wherein
the upper guide layer and the lower guide layer are formed of AlGaAs.

8. The semiconductor laser device according to claim 4, wherein
the upper guide layer and the lower guide layer are formed of AlGaAs.

9. The semiconductor laser device according to claim 7, wherein
an Al mole fraction of the upper guide layer and the lower guide layer is more than 0.2.

10. The semiconductor laser device according to claim 8, wherein
an Al mole fraction of the upper guide layer and the lower guide layer is more than 0.2.

11. The semiconductor laser device according to claim 1, wherein
the well layer(s) has a compressive strain.

12. The semiconductor laser device according to claim 4, wherein
the well layer(s) has a compressive strain.

13. The semiconductor laser device according to claim 11, wherein
a quantity of an absolute value of the compressive strain is not more than 3.5%.

14. The semiconductor laser device according to claim 12, wherein
a quantity of an absolute value of the compressive strain is not more than 3.5%.

15. The semiconductor laser device according to claim 1, wherein
the barrier layers have a tensile strain.

16. The semiconductor laser device according to claim 4, wherein
the barrier layers have a tensile strain.

17. The semiconductor laser device according to claim 15, wherein
a quantity of the tensile strain is not more than 3.5%.

18. The semiconductor laser device according to claim 16, wherein
a quantity of the tensile strain is not more than 3.5%.

19. An optical disc unit wherein the semiconductor laser device of claim 1 is used.
